(19) United States
(12) Patent Application Publication
(10) Pub. No.: US 2026/0247649 A1
(43) Pub. Date: Aug. 20, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Yosuke KAJIWARA, Yokohama Kanagawa (JP); Tatsuo SHIMIZU, Shinagawa Tokyo (JP); Hideyuki TOMIZAWA, Kita Tokyo (JP); Miyoko SHIMADA, Yokohama Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/448,183

(22) Filed: Jan. 14, 2026

(30) Foreign Application Priority Data
Feb. 18, 2025 (JP) 2025-024435

(51) Int. Cl. H10D 30/47; H10D 62/10; H10D 62/824; H10D 64/27

(52) U.S. Cl. CPC H10D 30/475; H10D 30/478; H10D 62/102; H10D 62/824; H10D 64/514; H10D 64/518; H10D 64/519

(57) ABSTRACT

According to one embodiment, a semiconductor device includes first to third electrodes, and a semiconductor member. The first and second electrodes extend along a first direction. The semiconductor member includes a first semiconductor region including Alₓ₁Ga₁₋ₓ₁N, and a second semiconductor region including Alₓ₂Ga₁₋ₓ₂N. The second semiconductor region includes a first semiconductor portion including a first side face and a second semiconductor portion including a second side face. The first side face extends linearly along the first direction. The second side face includes a plurality of first portions along a first portion direction and a plurality of second portions along a second portion direction. One of the plurality of first portions is between one of the plurality of second portions and another one of the plurality of second portions. The first portion direction is inclined with respect to the second direction.

### CROSS-REFERENCE TO RELATED APPLICATIONS

This application is based upon and claims the benefit of priority from Japanese Patent Application No. 2025-024435, filed on Feb. 18, 2025; the entire contents of which are incorporated herein by reference.

### FIELD

Embodiments described herein relate generally to a semiconductor device.

### BACKGROUND

For example, it is desired to improve the characteristics of semiconductor devices such as transistors.

### BRIEF DESCRIPTION OF THE DRAWINGS

FIGS. 1A and 1B are schematic views illustrating a semiconductor device according to a first embodiment;

FIG. 2 is a graph illustrating the characteristics of semiconductor devices;

FIGS. 3A and 3B are schematic diagrams illustrating semiconductor devices according to the first embodiment;

FIGS. 4A and 4B are schematic diagrams illustrating semiconductor devices according to the first embodiment;

FIGS. 5A and 5B are schematic diagrams illustrating semiconductor devices according to the first embodiment;

FIGS. 6A and 6B are schematic diagrams illustrating semiconductor devices according to the first embodiment;

FIG. 7 is a schematic plan view illustrating a semiconductor device according to a second embodiment; and

FIGS. 8A and 8B are schematic views illustrating a semiconductor device according to a third embodiment.

### DETAILED DESCRIPTION

According to one embodiment, a semiconductor device includes a first electrode, a second electrode, a third electrode, and a semiconductor member. The first electrode extends along a first direction. The second electrode extends along the first direction. A second direction from the first electrode to the second electrode crosses the first direction. The third electrode includes a first electrode portion extending along the first direction. A position of the first electrode portion in the second direction is between a first electrode position of the first electrode in the second direction and a second electrode position of the second electrode in the second direction. The semiconductor member includes a first semiconductor region including Alₓ₁Ga₁₋ₓ₁N (0≤x1<1), and a second semiconductor region including Alₓ₂Ga₁₋ₓ₂N (x1<x2≤1). A part of the second semiconductor region is between the first semiconductor region and the first electrode and between the first semiconductor region and the second electrode in a third direction crossing a plane including the first direction and the second direction. The second semiconductor region includes a first semiconductor portion including a first side face and a second semiconductor portion including a second side face. At least a part of the first electrode portion is between the first side face and the second side face in the second direction. The first side face extends linearly along the first direction. The second side face includes a plurality of first portions along a first portion direction and a plurality of second portions along a second portion direction. One of the plurality of first portions is between one of the plurality of second portions and another one of the plurality of second portions. The first portion direction is inclined with respect to the second direction. The second portion direction crosses the first portion direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

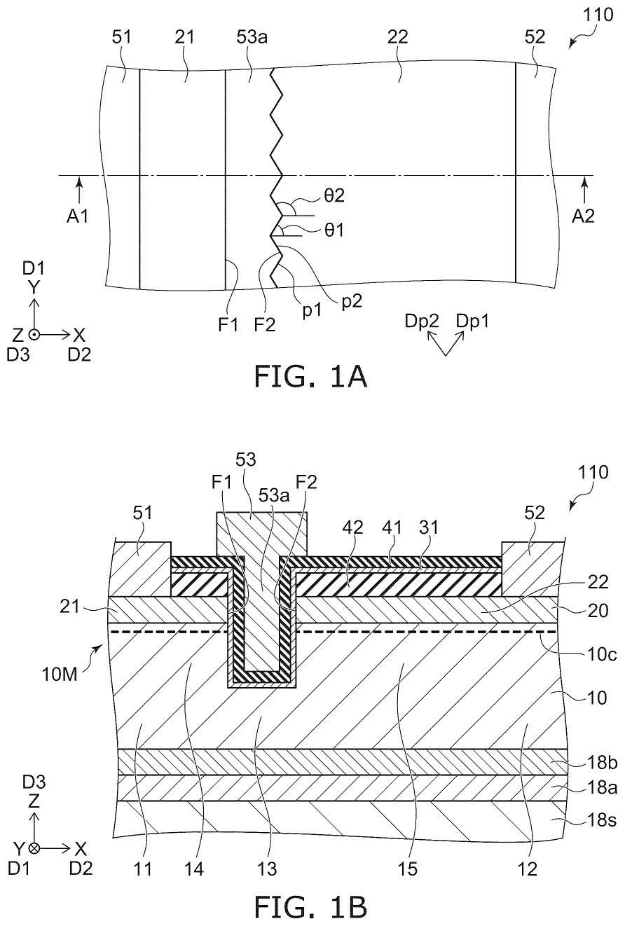

FIGS. 1A and 1B are schematic views illustrating a semiconductor device according to a first embodiment.

FIG. 1A is a plan view. FIG. 1B is a cross-sectional view taken along the line A1-A2 in FIG. 1A.

As shown in FIGS. 1A and 1B, a semiconductor device 110 according to the embodiment includes a first electrode 51, a second electrode 52, a third electrode 53, and a semiconductor member 10M.

The first electrode 51 and the second electrode 52 extend along a first direction D1. The first direction D1 is defined as a Y-axis direction. A direction perpendicular to the Y-axis direction is defined as an X-axis direction. A direction perpendicular to the Y-axis direction and the X-axis direction is defined as a Z-axis direction.

A second direction D2 from the first electrode 51 to the second electrode 52 crosses the first direction D1. The second direction D2 may be perpendicular to the first direction D1. The second direction D2 is, for example, the X-axis direction.

The third electrode 53 includes a first electrode portion 53a. The first electrode portion 53a extends along the first direction D1. The third electrode 53 may extend along the first direction D1. A position of the first electrode portion 53a in the second direction D2 is between a position of the first electrode 51 in the second direction D2 (first electrode position) and a position of the second electrode 52 in the second direction D2 (second electrode position).

The semiconductor member 10M includes a first semiconductor region 10 including Alₓ₁Ga₁₋ₓ₁N (0≤x1<1) and a second semiconductor region 20 including Alₓ₂Ga₁₋ₓ₂N (x1<x2≤1). A composition ratio x1 may be, for example, not less than 0 and not more than 0.15. The first semiconductor region 10 may be a GaN layer. The composition ratio x2 may be, for example, not less than 0.1 and not more than 0.4. The second semiconductor region 20 may be, for example, an AlGaN layer.

A part of the second semiconductor region 20 is located between the first semiconductor region 10 and the first electrode 51, and between the first semiconductor region 10 and the second electrode 52, in a third direction D3. The third direction D3 crosses a plane including the first direction D1 and the second direction D2.

The second semiconductor region 20 includes a first semiconductor portion 21 including a first side face F1 and a second semiconductor portion 22 including a second side face F2. At least a part of the first electrode portion 53a is located between the first side face F1 and the second side face F2 in the second direction D2.

As shown in FIG. 1A, the first side face F1 extends linearly along the first direction D1. The second side face F2 includes a plurality of first portions p1 along a first partial direction Dp1 and a plurality of second portions p2 along a second partial direction Dp2. The first partial direction Dp1 and the second partial direction Dp2 are included in, for example, a plane including the first direction D1 and the second direction D2. One of the plurality of first portions p1 is between one of the plurality of second portions p2 and another one of the plurality of second portions p2. One of the plurality of second portions p2 is between one of the plurality of first portions p1 and another one of the plurality of first portions p1.

The first partial direction Dp1 is inclined with respect to the second direction D2. The first partial direction Dp1 may be inclined with respect to the first direction D1. The second partial direction Dp2 crosses the first partial direction Dp1. In this example, the second partial direction Dp2 is also inclined with respect to the second direction D2. The second side face F2 is, for example, zigzag-shaped. In the first direction D1, a part of the second semiconductor portion 22 is located between the first portion p1 and the second portion p2.

In the semiconductor device 110, a current flowing between the first electrode 51 and the second electrode 52 can be controlled by a potential of the third electrode 53. The potential of the third electrode 53 may be, for example, based on a potential of the first electrode 51. The first electrode 51 functions as one of a source electrode and a drain electrode. The second electrode 52 functions as the other one of a source electrode and a drain electrode. The third electrode 53 functions as a gate electrode. The semiconductor device 110 is, for example, a transistor.

The first semiconductor region 10 includes a portion facing the second semiconductor region 20. A carrier region 10c is formed in this portion. The carrier region 10c is, for example, a two-dimensional electron gas. The semiconductor device 110 is, for example, a HEMT (High Electron Mobility Transistor).

In this example, a distance between the first electrode 51 and the third electrode 53 is shorter than a distance between the third electrode 53 and the second electrode 52. In this case, the first electrode 51 functions as a source electrode. Stable operation is easily achieved.

As already explained, in this embodiment, the first side face F1 and the second side face F2 have different shapes. Due to the different shapes, the crystal orientations of the semiconductor member 10M are different between these side faces. This results in favorable characteristics, as explained below.

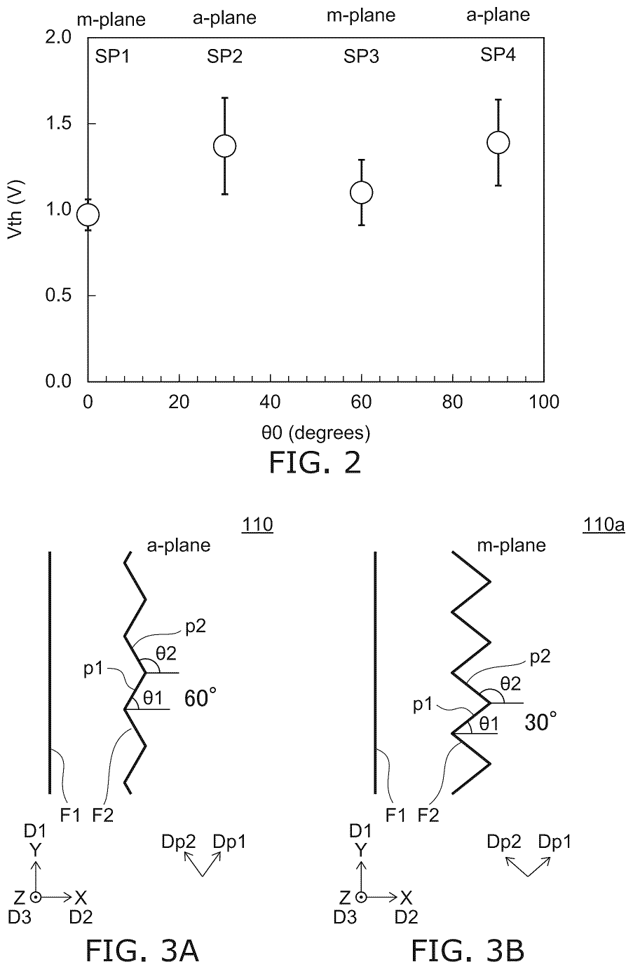

FIG. 2 is a graph illustrating the characteristics of semiconductor devices.

FIG. 2 illustrates the characteristics of the first sample SP 1, second sample SP2, third sample SP3, and fourth sample SP4. In these samples, the first side face F1 and the second side face F2 are linear and parallel to each other. In these samples, the crystal orientations of the two side faces are different. The horizontal axis of FIG. 2 is an angle θ0 between these side faces and the reference direction of the semiconductor crystal orientation. The angle θ0 corresponds to the angle between the first direction D1 and the reference direction.

In the first sample SP1, for which the angle θ0 is 0 degrees, the two side faces are aligned along an m-plane of the semiconductor member 10M. In the second sample SP2, where the angle θ0 is 30 degrees, the two side faces are aligned along an a-plane of the semiconductor member 10M. In the third sample SP3, where the angle θ0 is 60 degrees, the two side faces are aligned along another m-plane of the semiconductor member 10M. In the fourth sample SP4, where the angle θ0 is 90 degrees, the two side faces are aligned along another a-plane of the semiconductor member 10M. The vertical axis is the threshold voltage Vth.

As shown in FIG. 2, the threshold voltage Vth when the side face is the a-plane is higher than the threshold voltage Vth when the side face is the m-plane. This is a finding newly obtained through experiments conducted independently by the inventors.

On the other hand, generally, different crystal orientations of the side face result in different mobilities and different on-resistances. Based on the experiments conducted independently by the inventors, for example, the on-resistance when the side face is the a-plane is higher than the on-resistance when the side face is the m-plane. Therefore, in a case wherein both side faces are the a-plane, a high threshold value is obtained, but the on-resistance increases.

In the embodiments, the first side face F1 and the second side face F2 have different shapes. This, for example, can suppress an increase in the on-resistance while obtaining a high threshold voltage. Alternatively, a relatively high threshold voltage can be maintained while obtaining a low on-resistance. In embodiments, a semiconductor device with improved characteristics can be produced.

In one example, the first side face F1 may extend along the m-plane of the semiconductor member 10M. In this case, the two portions included in the second side face F2 may extend along the two a-planes of the semiconductor member 10M.

As shown in FIG. 1, the second partial direction Dp2 may be inclined in the opposite direction to the first partial direction Dp1 with respect to the second direction D2.

For example, an angle between the first partial direction Dp1 and the second direction D2 is defined as a first angle θ1. An angle between the second partial direction Dp2 and the second direction D2 is defined as a second angle θ2. These angles are, for example, counterclockwise angles. In this embodiment, a sum of the first angle θ1 and the second angle θ2 may be, for example, substantially 180 degrees. For example, the sum of the first angle θ1 and the second angle θ2 may be not less than 160 degrees and not more than 200 degrees. The sum angle may also be not less than 170 degrees and not more than 190 degrees. This makes it easier to consistently obtain a good threshold voltage and good on-resistance.

The angle between the first partial direction Dp1 and the second direction D2 (first angle θ1) may be, for example, substantially 30 degrees or 60 degrees. The first angle θ1 may be, for example, not less than 20 degrees and not more than 40 degrees, or not less than 50 degrees and not more than 70 degrees. This makes it easier to consistently achieve a good threshold voltage and good on-resistance.

In the semiconductor device according to this embodiment, as shown in FIG. 1B, the first semiconductor region 10 may include a first partial region 11, a second partial region 12, a third partial region 13, a fourth partial region 14, and a fifth partial region 15. A direction from the first partial region 11 to the first electrode 51 is along the third direction D3. A direction from the second partial region 12 to the second electrode 52 is along the third direction D3.

A direction from the third partial region 13 to the first electrode portion 53a is along the third direction D3. A fourth position of the fourth partial region 14 in the second direction D2 is between a first position of the first partial region 11 in the second direction D2 and a third position of the third partial region 13 in the second direction D2. A fifth position of the fifth partial region 15 in the second direction D2 is between the third position and a second position of the second electrode 52 in the second direction D2.

A direction from the fourth partial region 14 to the first semiconductor portion 21 is along the third direction D3. A direction from the fifth partial region 15 to the second semiconductor portion 22 is along the third direction D3.

For example, a part of the first electrode portion 53a may be located between the fourth partial region 14 and the fifth partial region 15 in the second direction D2. A length of the first side face F1 and the second side face F2 along the third direction D3 is preferably not less than 100 nm and not more than 400 nm. By the length of the first side face F1 and the second side face F2 along the third direction D3 being 100 nm or more, a high threshold voltage can be obtained. Leakage current can be decreased For example, it is easy to control the shape of the side face, making it easy to obtain an m-plane or a-plane shape. By the length of the first side face F1 and the second side face F2 along the third direction D3 being 400 nm or less, a low on-resistance can be obtained. The length of the first side face F1 and the second side face F2 along the third direction D3 may substantially correspond to the depth of the recess.

The semiconductor device 110 may include a base 18s and a nitride layer 18a. The base 18s may include, for example, a silicon substrate. The nitride layer 18a is provided between the base 18s and the first semiconductor region 10. The nitride layer 18a includes, for example, Al, Ga, and N. The nitride layer 18a is, for example, a buffer layer.

The semiconductor device 110 may further include an intermediate region 18b. The intermediate region 18b is located between the nitride layer 18a and the first semiconductor region 10. The intermediate region 18b includes, for example, Alₓ₃Ga₁₋ₓ₃N (0≤x3<1, x3<z2). The intermediate region 18b may be, for example, a GaN layer. A carbon concentration in the intermediate region 18b is higher than a carbon concentration in the first semiconductor region 10. The carbon-containing intermediate region 18b can suppress leakage current, for example.

As shown in FIG. 1B, the semiconductor device 110 may include a compound layer 31. At least a part of the compound layer 31 is provided between the semiconductor member 10M and the third electrode 53. The compound layer 31 includes, for example, Al_{z1}Ga_{1-z1}N (0<z1≤1, x2<z1). The composition ratio z1 may be, for example, not less than 0.8 and not more than 1. The compound layer 31 includes, for example, AlN.

The semiconductor device 110 may include a first insulating member 41. The first insulating member 41 is located between the compound layer 31 and the first electrode portion 53a. The first insulating member 41 may include, for example, silicon oxide.

The semiconductor device 110 may include a second insulating member 42. The first semiconductor portion 21 is provided between the fourth partial region 14 and a part of the second insulating member 42. The second semiconductor portion 22 is provided between the fifth partial region 15 and a part of the second insulating member 42. The first insulating member 41 includes, for example, silicon and at least one element selected from the group consisting of nitrogen and oxygen. The second semiconductor region 20 is protected by the second insulating member 42.

Below, several examples of the first side face F1 and the second side face F2 will be described.

FIGS. 3A and 3B are schematic diagrams illustrating semiconductor devices according to the first embodiment.

FIG. 3A illustrates the first side face F1 and the second side face F2 of the semiconductor device 110 described above. In the semiconductor device 110, two portions included in the second side face F2 are along the a-plane. The first angle θ1 is substantially 60 degrees. The second angle θ2 is 120 degrees.

As shown in FIG. 3B, in a semiconductor device 110a according to the embodiment, the two portions included in the second side face F2 are along the m-plane. The first angle θ1 is substantially 30 degrees. The second angle θ2 is 150 degrees.

For example, one of the plurality of first portions p1 is along an a-plane of the semiconductor member 10M. One of the plurality of second portions p2 is along another one of the a-plane of the semiconductor member 10M.

Alternatively, one of the plurality of first portions p1 is along an m-plane of the semiconductor member 10M. One of the plurality of second portions p2 is along another one of the m-plane of the semiconductor member 10M.

In the semiconductor device 110 and the semiconductor device 110a, the gate width at the zigzag-shaped second side face F2 can be increased. This results in a low on-resistance.

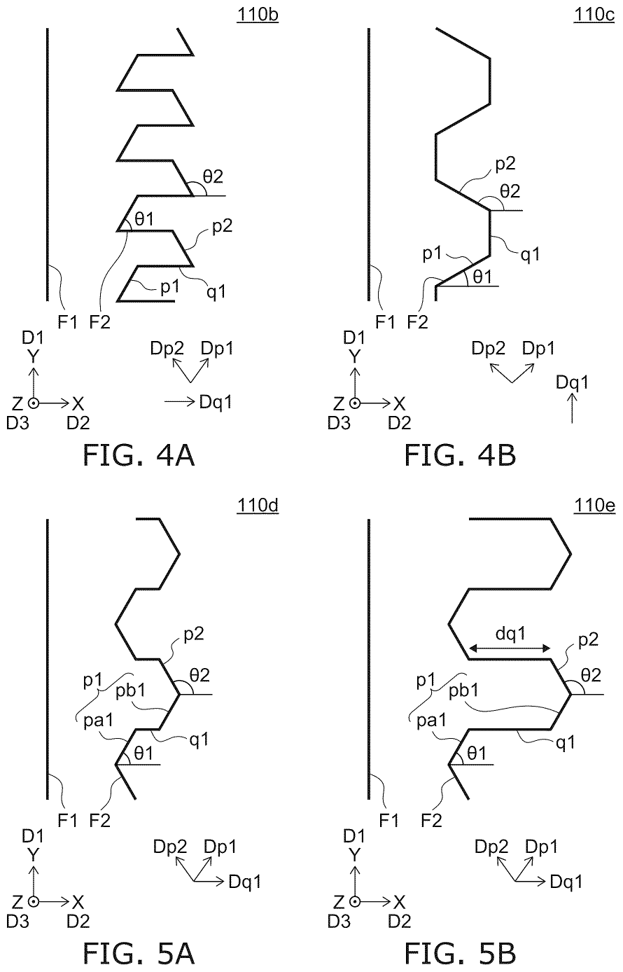

FIGS. 4A and 4B are schematic diagrams illustrating semiconductor devices according to the first embodiment.

As shown in FIG. 4A, in a semiconductor device 110b according to the embodiment, the second side face F2 further includes a plurality of first intermediate portions q1 along a first intermediate portion direction Dq1. One of the plurality of first intermediate portions q1 is located between one of the plurality of first portions p1 and one of the plurality of second portions p2. The first intermediate portion direction Dq1 crosses the first portion direction Dp1 and the second portion direction Dp2. In this example, the first intermediate portion direction Dq1 is aling the second direction D2. The first angle θ1 may be, for example, 60 degrees. The second angle θ2 may be, for example, 120 degrees.

As shown in FIG. 4B, in a semiconductor device 110c according to the embodiment, the second side face F2 also includes the plurality of first intermediate portions q1. In this example, the first intermediate portion direction Dq1 is along the first direction D1. The first angle θ1 may be, for example, 30 degrees. The second angle θ2 may be, for example, 150 degrees. In the first direction D1, a part of the second semiconductor portion 22 is located between two first intermediate portions q1.

Thus, the first intermediate portion direction Dq1 may be along the first direction D1 or the second direction D2. Thereby, the gate width at the second side face F2 can be increased. Thereby, a low on-resistance can be obtained.

FIGS. 5A and 5B are schematic diagrams illustrating semiconductor devices according to the first embodiment.

As shown in FIG. 5A, in a semiconductor device 110d according to the embodiment, the second side face F2 includes the plurality of first intermediate portions q1 along the first intermediate portion direction Dq1. One of the plurality of first intermediate portions q1 is located between a portion pa1 of the one of the plurality of first portions p1 and another portion pb1 of the one of the plurality of first portions p1. In this example, the first intermediate portion direction Dq1 also crosses the first portion direction Dp1 and the second portion direction Dp2. In this example, the first intermediate portion direction Dq1 is along the second direction D2. The first angle θ1 may be, for example, 60 degrees. The second angle θ2 may be, for example, 120 degrees.

As shown in FIG. 5B, in a semiconductor device 110e according to the embodiment, the second side face F2 also includes plurality of first intermediate portions q1. In this example, a length dq1 of one of the plurality of first intermediate portions q1 is longer than the portion pa1 of the one of the plurality of first portions p1. The length dq1 is also longer than the other portion pb1 of the one of the plurality of first portions p1. The length dq1 can be arbitrarily long. The gate width at the second side face F2 can be increased. Thereby, a low on-resistance can be obtained.

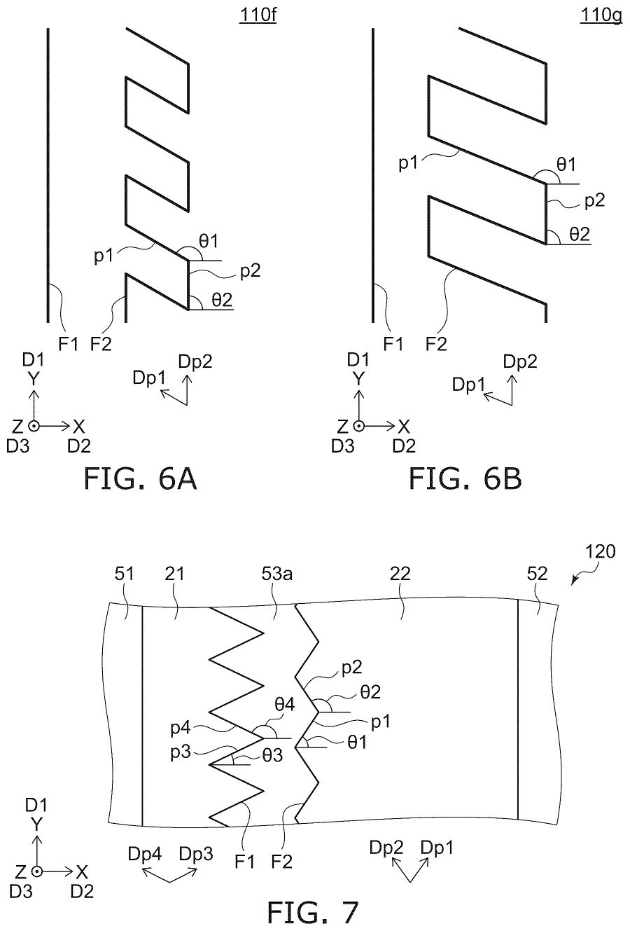

FIGS. 6A and 6B are schematic diagrams illustrating semiconductor devices according to the first embodiment.

As shown in FIG. 6A, in a semiconductor device 110f according to the embodiment, the second side face F2 includes the plurality of first portions p1 along the first partial direction Dp1 and the plurality of second portions p2 along the second partial direction Dp2. The first partial direction Dp1 is inclined with respect to the second direction D2. In this example, the second partial direction Dp2 is along the first direction D1. The second angle θ2 is substantially 90 degrees. The first angle θ1 may be, for example, 120 degrees. Thereby, the gate width at the second side face F2 can be increased. Thereby, a low on-resistance can be obtained.

As shown in FIG. 6B, in a semiconductor device 110g according to the embodiment, the first partial direction Dp1 is also inclined with respect to the second direction D2, and the second partial direction Dp2 is along the first direction D1. In the semiconductor device 110g, the length of each of the plurality of first portions p1 is longer than the length of each of the plurality of second portions p2. The length of each of the plurality of first portions p1 can be set to any desired length. Thereby, the gate width at the second side face F2 can be increased. Thereby, a lower on-resistance can be obtained.

### Second Embodiment

FIG. 7 is a schematic plan view illustrating a semiconductor device according to a second embodiment.

As shown in FIG. 7, in a semiconductor device 120 according to the embodiment, the shapes of the side faces of the first semiconductor portion 21 and the second semiconductor portion 22 differ from those in the semiconductor device according to the first embodiment. The configuration of the semiconductor device 120 except for this may be the same as the configuration of the semiconductor device according to the first embodiment.

In the semiconductor device 120, the second semiconductor region 20 includes the first semiconductor portion 21 including the first side face F1 and the second semiconductor portion 22 including the second side face F2. At least a part of the first electrode portion 53a is located between the first side face F1 and the second side face F2 in the second direction D2.

The second side face F2 includes the plurality of first portions p1 along the first partial direction Dp1 and the plurality of second portions p2 extending along the second partial direction Dp2. One of the plurality of first portions p1 is between one of the plurality of second portions p2 and another one of the plurality of second portions p2. One of the plurality of second portions p2 is between one of the plurality of first portions p1 and another one of the plurality of first portions p1. The first portion direction Dp1 is inclined with respect to the second direction D2. The second portion direction Dp2 crosses the first portion direction Dp1.

The first side face F1 includes a plurality of third portions p3 along a third partial direction Dp3 and a plurality of fourth portions p4 along a fourth partial direction Dp4. One of the plurality of third portions p3 is located between one of the plurality of fourth portions p4 and another one of the plurality of fourth portions p4. One of the plurality of fourth portions p4 is located between one of the plurality of third portions p3 and another one of the plurality of third portions p3. The third partial direction Dp3 is inclined with respect to the second direction D2. The fourth partial direction Dp4 crosses the third partial direction Dp3.

The first angle θ1 between the first partial direction Dp1 and the second direction D2 is different from a third angle θ3 between the third partial direction Dp3 and the second direction D2, and is different from a fourth angle θ4 between the fourth partial direction Dp4 and the second direction D2.

The second angle θ2 between the second partial direction Dp2 and the second direction D2 is different from the third angle θ3 and different from the fourth angle θ4.

In the semiconductor device 120, for example, the gate length can be increased at each of the first side face F1 and the second side face F2. A low on-resistance can be obtained.

For example, the first angle θ1 can be substantially 60 degrees. For example, the second angle θ2 can be substantially 120 degrees. For example, the third angle θ3 can be substantially 30 degrees. For example, the fourth angle θ4 can be substantially 150 degrees. For example, a high threshold voltage Vth and a low on-resistance can be obtained.

The configuration of the second side face F2 in the semiconductor device 120 described in relation to the semiconductor device of the first embodiment can be applied to the second side face F2. The configuration of the second side face F2 in relation to the semiconductor device of the first embodiment can be applied to the first side face F1 in the semiconductor device 120.

For example, the second partial direction Dp2 may be inclined in the opposite direction to the first partial direction Dp1 with respect to the second direction D2. The fourth partial direction Dp4 is inclined in the opposite direction to the third partial direction Dp3 with respect to the second direction D2.

For example, a sum of the first angle θ1 and the second angle θ2 may be not less than 160 degrees and not more than 200 degrees. A sum of the third angle θ3 and the fourth angle θ4 may be not less than 160 degrees and not more than 200 degrees.

For example, one of the plurality of first portions p1 is along the a-plane of the semiconductor member 10M, and one of the plurality of second portions p2 is along another a-plane of the semiconductor member 10M. One of the plurality of third portions p3 is along the m-plane of the semiconductor member 10M, and one of the plurality of fourth portions p4 is along another m-plane of the semiconductor member 10M.

For example, the second side face F2 may further include plurality of first intermediate portions q1 along the first intermediate portion direction Dq1 (see FIGS. 4A to 5B). One of the plurality of first intermediate portions q1 is located between one of the plurality of first portions p1 and one of the plurality of second portions p2. The first intermediate portion direction Dq1 crosses the first portion direction Dp1 and crosses the second portion direction Dp2.

For example, a high threshold voltage can be obtained while suppressing an increase in on-resistance. A low on-resistance can be obtained while maintaining a relatively high threshold voltage. A semiconductor device with improved characteristics can be achieved.

### Third Embodiment

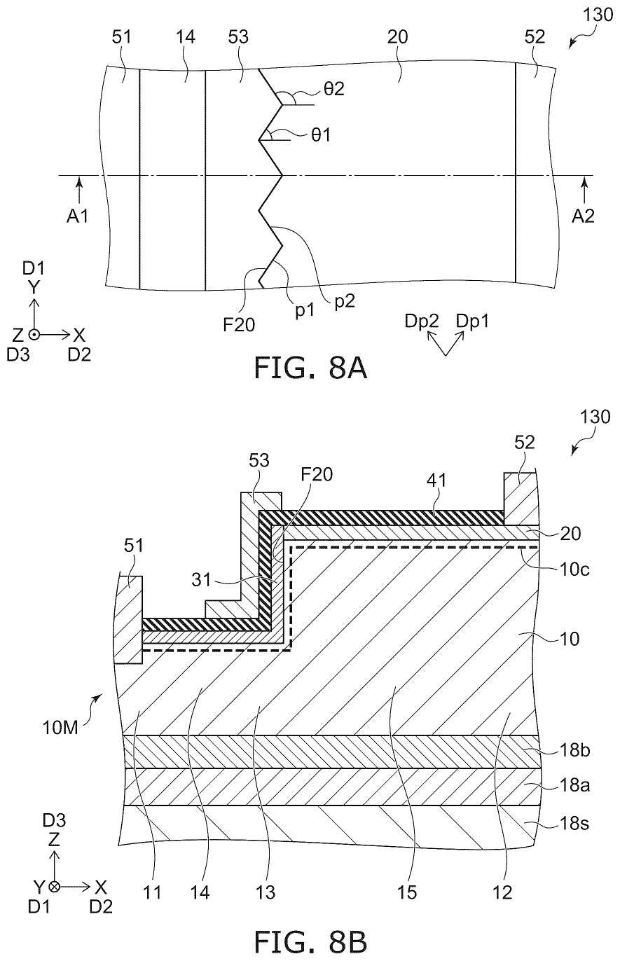

FIGS. 8A and 8B are schematic views illustrating a semiconductor device according to a third embodiment.

FIG. 8A is a plan view. FIG. 8B is a cross-sectional view taken along the line 1-A2 in FIG. 8A.

As shown in FIGS. 8A and 8B, a semiconductor device 130 according to the embodiment includes the first electrode 51, the second electrode 52, the third electrode 53, and the semiconductor member 10M.

The first electrode 51, the second electrode 52, and the third electrode 53 extend along the first direction D1. The second direction D2 extending from the first electrode 51 to the second electrode 52 crosses the first direction D1. The position of the third electrode 53 in the second direction D2 is between the first electrode position of the first electrode 51 in the second direction D2 and the second electrode position of the second electrode 52 in the second direction D2.

The semiconductor member 10M includes the first semiconductor region 10 including Alₓ₁Ga₁₋ₓ₁N (0≤x1<1) and the second semiconductor region 20 including Alₓ₂Ga₁₋ₓ₂N (x1<x2≤1).

The first semiconductor region 10 includes the first partial region 11, the second partial region 12, the third partial region 13, the fourth partial region 14, and the fifth partial region 15. The direction from the first partial region 11 to the first electrode 51 is along the third direction D3 that crosses a plane including the first direction D1 and the second direction D2.

The direction from the second partial region 12 to the second electrode 52 is along the third direction D3. The direction from the third partial region 13 to the third electrode 53 is along the third direction D3. The fourth position of the fourth partial region 14 in the second direction D2 is between the first position of the first partial region 11 in the second direction D2 and the third position of the third partial region 13 in the second direction D2. The fifth position of the fifth partial region 15 in the second direction D2 is between the third position and the second position of the second electrode 52 in the second direction D2.

A direction from the fifth partial region 15 to the second semiconductor region 20 is along the third direction D3. The direction from a part of the third electrode 53 to the fifth partial region 15 is along the second direction D2.

The second semiconductor region 20 includes a side face F20 facing the third electrode 53 in the second direction D2. The side face F20 includes the plurality of first portions p1 along the first partial direction Dp1 and the plurality of second portions p2 along the second partial direction Dp2.

One of the plurality of first portions p1 is located between one of the plurality of second portions p2 and another one of the plurality of second portions p2. One of the plurality of second portions p2 is located between one of the plurality of first portions p1 and another one of the plurality of first portions p1.

The first partial direction Dp1 is inclined with respect to the second direction D2. The second partial direction Dp2 crosses the first partial direction Dp1.

In the semiconductor device 130, for example, a high threshold voltage can be obtained. In the semiconductor device 130, for example, a low on-resistance can be obtained. In the embodiment, a semiconductor device with improved characteristics can be obtained.

The various configurations described with respect to the second side face F2 may be applied to the side face F20 of the semiconductor device 130. For example, the second partial direction Dp2 may be inclined in the opposite direction to the first partial direction Dp1 with respect to the second direction D2. The length of the side face F20 along the third direction D3 is preferably not less than 100 nm and not more than 400 nm. By the length of the side face F20 along the third direction D3 being 100 nm or more, a high threshold voltage is easily obtained. Leakage current is easily reduced. The shape of the side face is easily controlled, making it easy to obtain an m-plane or a-plane shape. By the length of the side face F20 along the third direction D3 being 400 nm or less, a low on-resistance is easily obtained.

For example, the sum of the first angle θ1 between the first partial direction Dp1 and the second direction D2 and the second angle θ2 between the second partial direction Dp2 and the second direction D2 may be not less than 160 degrees and not more than 200 degrees.

For example, one of the plurality of first portions p1 is along a-plane of the semiconductor member 10M, and one of the plurality of second portions p2 is along another a-plane of the semiconductor member 10M.

One of the plurality of first portions p1 is along the m-plane of the semiconductor member 10M, and one of the plurality of second portions p2 is along another m-plane of the semiconductor member 10M.

In the embodiment, information regarding the shape of the semiconductor region is obtained, for example, from electron microscope images. Information regarding the composition and element concentration is obtained, for example, from EDX (Energy Dispersive X-ray Spectroscopy) or SIMS (Secondary Ion Mass Spectrometry). Information regarding the composition may also be obtained, for example, from reciprocal lattice space mapping.

The embodiment may include the following Technical proposals:

### Technical Proposal 1

A semiconductor device, comprising:
a first electrode extending along a first direction;
a second electrode extending along the first direction, a second direction from the first electrode to the second electrode crossing the first direction;
a third electrode including a first electrode portion extending along the first direction, a position of the first electrode portion in the second direction being between a first electrode position of the first electrode in the second direction and a second electrode position of the second electrode in the second direction; and
a semiconductor member,
the semiconductor member including:
   a first semiconductor region including Alₓ₁Ga₁₋ₓ₁N (0 ≤x1<1), and
   a second semiconductor region including Alₓ₂Ga₁₋ₓ₂N (x1<x2≤1),
a part of the second semiconductor region being between the first semiconductor region and the first electrode and between the first semiconductor region and the second electrode in a third direction crossing a plane including the first direction and the second direction,
the second semiconductor region including a first semiconductor portion including a first side face and a second semiconductor portion including a second side face,
at least a part of the first electrode portion being between the first side face and the second side face in the second direction,
the first side face extending linearly along the first direction,
the second side face including a plurality of first portions along a first portion direction and a plurality of second portions along a second portion direction,
one of the plurality of first portions being between one of the plurality of second portions and another one of the plurality of second portions,
the first portion direction being inclined with respect to the second direction, and
the second portion direction crossing the first portion direction.

### Technical Proposal 2

The semiconductor device according to Technical proposal 1, wherein
the second portion direction is inclined in an opposite direction to the first portion direction with respect to the second direction.

### Technical Proposal 3

The semiconductor device according to Technical proposal 2, wherein
a sum of a first angle between the first partial direction and the second direction and a second angle between the second partial direction and the second direction is not less than 160 degrees and not more than 200 degrees.

### Technical Proposal 4

The semiconductor device according to Technical proposal 2, wherein
an angle between the first direction and the second direction is not less than 20 degrees and not more than 40 degrees, or not less than 50 degrees and not more than 70 degrees.

### Technical Proposal 5

The semiconductor device according to any one of Technical proposals 2 to 4, wherein
one of the first portions is along an a-plane of the semiconductor member and one of the second portions is along another a-plane of the semiconductor member, or
one of the first portions is along an m-plane of the semiconductor member and one of the second portions is along another m-plane of the semiconductor member.

### Technical Proposal 6

The semiconductor device according to any one of Technical proposals 2 to 5, wherein
the second side further includes a plurality of first intermediate portions along a first intermediate portion direction,
one of the plurality of first intermediate portions is between the one of the plurality of first portions and the one of the plurality of second portions, and
the first intermediate portion direction crosses the first portion direction and crosses the second portion direction.

### Technical Proposal 7

The semiconductor device according to Technical proposal 6, wherein
the first intermediate portion direction is along the first direction or the second direction.

### Technical Proposal 8

The semiconductor device according to any one of Technical proposals 2 to 5, wherein
the second side further includes a plurality of first intermediate portions along a first intermediate portion direction,
one of the plurality of first intermediate portions is between a part of the one of the plurality of first portions and another part of the one of the plurality of first portions, and
the first intermediate portion direction crosses the first portion direction and crosses the second portion direction.

### Technical Proposal 9

The semiconductor device according to Technical proposal 1, wherein
the second portion direction is along the first direction.

### Technical Proposal 10

A semiconductor device, comprising:
a first electrode extending along a first direction;
a second electrode extending along the first direction, a second direction from the first electrode to the second electrode crossing the first direction;
a third electrode including a first electrode portion extending along the first direction, a position of the first electrode portion in the second direction being a first electrode position of the first electrode in the second direction and a second electrode position of the second electrode in the second direction; and
a semiconductor member;
the semiconductor member including:
   a first semiconductor region including Alₓ₁Ga₁₋ₓ₁N (0 ≤x1<1), and
   a second semiconductor region including Alₓ₂Ga₁₋ₓ₂N (x1<x2≤1),
a part of the second semiconductor region being between the first semiconductor region and the first electrode and between the first semiconductor region and the second electrode in a third direction crossing a plane including the first direction and the second direction,
the second semiconductor region includes a first semiconductor portion including a first side face and a second semiconductor portion including a second side face,
at least a part of the first electrode portion being between the first side face and the second side face in the second direction,
the second side face including a plurality of first portions along a first portion direction and a plurality of second portions along a second portion direction,
one of the plurality of first portions being between one of the plurality of second portions and another one of the plurality of second portions,
the first portion direction being inclined with respect to the second direction,
the second portion direction crossing the first portion direction,
the first side including a plurality of third portions along a third portion direction and a plurality of fourth portions along a fourth portion direction, and
one of the plurality of third portions being between one of the plurality of fourth portions and another one of the plurality of fourth portions,
the third partial direction being inclined with respect to the second direction,
the fourth partial direction crossing the third partial direction,
a first angle between the first partial direction and the second direction being different from a third angle between the third partial direction and the second direction and different from a fourth angle between the fourth partial direction and the second direction, and
a second angle between the second partial direction and the second direction being different from the third angle and different from the fourth angle.

### Technical Proposal 11

The semiconductor device according to Technical proposal 10, wherein
the second portion direction is inclined in an opposite direction to the first portion direction relative to the second direction, and
the fourth portion direction is inclined in an opposite direction to the third portion direction relative to the second direction.

### Technical Proposal 12

The semiconductor device according to Technical proposal 10, wherein
a sum of the first angle and the second angle is not less than 160 degrees and not more than 200 degrees, and
a sum of the third angle and the fourth angle is not less than 160 degrees and not more than 200 degrees.

### Technical Proposal 13

The semiconductor device according to any one of Technical proposals 10 to 12, wherein
one of the first portions is along an a-plane of the semiconductor member, and one of the second portions is along another a-plane of the semiconductor member, and
one of the third portions is along an m-plane of the semiconductor member, and one of the fourth portions is along another m-plane of the semiconductor member.

### Technical Proposal 14

The semiconductor device according to any one of Technical proposals 10 to 13, wherein
the second side further includes a plurality of first intermediate portions along a first intermediate portion direction,
one of the plurality of first intermediate portions is between one of the plurality of first portions and one of the plurality of second portions, and
the first intermediate portion direction crosses the first portion direction and crosses the second portion direction.

### Technical Proposal 15

The semiconductor device according to any one of Technical proposals 1 to 14, wherein
the first semiconductor region includes a first partial region, a second partial region, a third partial region, a fourth partial region, and a fifth partial region,
a direction from the first partial region to the first electrode is along the third direction,
a direction from the second partial region to the second electrode is along the third direction,
a direction from the third partial region to the first electrode portion is along the third direction,
a fourth position of the fourth partial region in the second direction is between a first position of the first partial region in the second direction and a third position of the third partial region in the second direction,
a fifth position of the fifth partial region in the second direction is between the third position and a second position of the second electrode in the second direction,
a direction from the fourth partial region to the first semiconductor portion is along the third direction, and
a direction from the fifth region to the second semiconductor region is along the third direction.

### Technical Proposal 16

The semiconductor device according to Technical proposal 15, wherein
a part of the first electrode portion is between the fourth partial region and the fifth partial region in the second direction.

### Technical Proposal 17

A semiconductor device, comprising:
a first electrode extending along a first direction;
a second electrode extending along the first direction, a second direction from the first electrode to the second electrode crossing the first direction;
a third electrode extending along the first direction, a position of the third electrode in the second direction being between a first electrode position of the first electrode in the second direction and a second electrode position of the second electrode in the second direction; and
a semiconductor member,
the semiconductor member includes:
   a first semiconductor region including Alₓ₁Ga₁₋ₓ₁N (0 ≤x1<1), and
   a second semiconductor region including Alₓ₂Ga₁₋ₓ₂N (x1<x2≤1),
the first semiconductor region including a first partial region, a second partial region, a third partial region, a fourth partial region, and a fifth partial region,
a direction from the first partial region to the first electrode being along a third direction crossing a plane including the first direction and the second direction,
a direction from the second partial region to the second electrode being along the third direction,
a direction from the third partial region to the third electrode being along the third direction,
a fourth position of the fourth partial region in the second direction being between a first position of the first partial region in the second direction and a third position of the third partial region in the second direction,
a fifth position of the fifth partial region in the second direction being between the third position and a second position of the second electrode in the second direction,
a direction from the fifth partial region to the second semiconductor region being along the third direction,
a direction from a part of the third electrode to the fifth partial region being along the second direction,
the second semiconductor region including a side face facing the third electrode in the second direction,
the side face including a plurality of first portions along a first partial direction and a plurality of second portions along a second partial direction,
one of the plurality of first portions being between one of the plurality of second portions and another one of the plurality of second portions,
the first portion direction being inclined with respect to the second direction, and
the second portion direction crossing the first portion direction.

### Technical Proposal 18

The semiconductor device according to Technical proposal 17, wherein
the second portion direction is inclined in an opposite direction to the first portion direction with respect to the second direction.

### Technical Proposal 19

The semiconductor device according to Technical proposal 18, wherein
a sum of the first angle between the first partial direction and the second direction and a second angle between the second partial direction and the second direction is not less than 160 degrees and not more than 200 degrees.

### Technical Proposal 20

The semiconductor device according to any one of Technical proposals 17 to 19, wherein
one of the first portions is along an a-plane of the semiconductor member and one of the second portions is along another a-plane of the semiconductor member, or
one of the first portions is along an m-plane of the semiconductor member and one of the second portions is along another m-plane of the semiconductor member.

According to the embodiment, a semiconductor device capable of improving characteristics is provided.

In the present specification, the term “electrically connected state” includes a state in which a plurality of conductors are physically in contact and a current flows between the plurality of conductors. The “state of being electrically connected” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, insulating members, bases, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode extending along a first direction;
a second electrode extending along the first direction, a second direction from the first electrode to the second electrode crossing the first direction;
a third electrode including a first electrode portion extending along the first direction, a position of the first electrode portion in the second direction being between a first electrode position of the first electrode in the second direction and a second electrode position of the second electrode in the second direction; and
a semiconductor member,
the semiconductor member including:
a first semiconductor region including Alₓ₁Ga₁₋ₓ₁N (0 ≤x1<1), and
a second semiconductor region including Alₓ₂Ga₁₋ₓ₂N (x1<x2≤1),
a part of the second semiconductor region being between the first semiconductor region and the first electrode and between the first semiconductor region and the second electrode in a third direction crossing a plane including the first direction and the second direction,
the second semiconductor region including a first semiconductor portion including a first side face and a second semiconductor portion including a second side face,
at least a part of the first electrode portion being between the first side face and the second side face in the second direction,
the first side face extending linearly along the first direction,
the second side face including a plurality of first portions along a first portion direction and a plurality of second portions along a second portion direction,
one of the plurality of first portions being between one of the plurality of second portions and another one of the plurality of second portions,
the first portion direction being inclined with respect to the second direction, and
the second portion direction crossing the first portion direction.

2. The semiconductor device according to claim 1, wherein
the second portion direction is inclined in an opposite direction to the first portion direction with respect to the second direction.

3. The semiconductor device according to claim 2, wherein
a sum of a first angle between the first partial direction and the second direction and a second angle between the second partial direction and the second direction is not less than 160 degrees and not more than 200 degrees.

4. The semiconductor device according to claim 2, wherein
an angle between the first direction and the second direction is not less than 20 degrees and not more than 40 degrees, or not less than 50 degrees and not more than 70 degrees.

5. The semiconductor device according to claim 2, wherein
one of the first portions is along an a-plane of the semiconductor member and one of the second portions is along another a-plane of the semiconductor member, or
one of the first portions is along an m-plane of the semiconductor member and one of the second portions is along another m-plane of the semiconductor member.

6. The semiconductor device according to claim 2, wherein
the second side further includes a plurality of first intermediate portions along a first intermediate portion direction,
one of the plurality of first intermediate portions is between the one of the plurality of first portions and the one of the plurality of second portions, and
the first intermediate portion direction crosses the first portion direction and crosses the second portion direction.

7. The semiconductor device according to claim 6, wherein
the first intermediate portion direction is along the first direction or the second direction.

8. The semiconductor device according to claim 2, wherein
the second side further includes a plurality of first intermediate portions along a first intermediate portion direction,
one of the plurality of first intermediate portions is between a part of the one of the plurality of first portions and another part of the one of the plurality of first portions, and
the first intermediate portion direction crosses the first portion direction and crosses the second portion direction.

9. The semiconductor device according to claim 1, wherein the second portion direction is along the first direction.

10. A semiconductor device, comprising:
a first electrode extending along a first direction;
a second electrode extending along the first direction, a second direction from the first electrode to the second electrode crossing the first direction;
a third electrode including a first electrode portion extending along the first direction, a position of the first electrode portion in the second direction being a first electrode position of the first electrode in the second direction and a second electrode position of the second electrode in the second direction; and
a semiconductor member;
the semiconductor member including:
a first semiconductor region including Alₓ₁Ga₁₋ₓ₁N (0 ≤x1<1), and
a second semiconductor region including Alₓ₂Ga₁₋ₓ₂N (x1<x2≤1),
a part of the second semiconductor region being between the first semiconductor region and the first electrode and between the first semiconductor region and the second electrode in a third direction crossing a plane including the first direction and the second direction,
the second semiconductor region includes a first semiconductor portion including a first side face and a second semiconductor portion including a second side face,
at least a part of the first electrode portion being between the first side face and the second side face in the second direction,
the second side face including a plurality of first portions along a first portion direction and a plurality of second portions along a second portion direction,
one of the plurality of first portions being between one of the plurality of second portions and another one of the plurality of second portions,
the first portion direction being inclined with respect to the second direction,
the second portion direction crossing the first portion direction,
the first side including a plurality of third portions along a third portion direction and a plurality of fourth portions along a fourth portion direction, and
one of the plurality of third portions being between one of the plurality of fourth portions and another one of the plurality of fourth portions,
the third partial direction being inclined with respect to the second direction,
the fourth partial direction crossing the third partial direction,
a first angle between the first partial direction and the second direction being different from a third angle between the third partial direction and the second direction and different from a fourth angle between the fourth partial direction and the second direction, and
a second angle between the second partial direction and the second direction being different from the third angle and different from the fourth angle.

11. The semiconductor device according to claim 10, wherein
the second portion direction is inclined in an opposite direction to the first portion direction relative to the second direction, and
the fourth portion direction is inclined in an opposite direction to the third portion direction relative to the second direction.

12. The semiconductor device according to claim 10, wherein
a sum of the first angle and the second angle is not less than 160 degrees and not more than 200 degrees, and
a sum of the third angle and the fourth angle is not less than 160 degrees and not more than 200 degrees.

13. The semiconductor device according to claim 10, wherein
one of the first portions is along an a-plane of the semiconductor member, and one of the second portions is along another a-plane of the semiconductor member, and
one of the third portions is along an m-plane of the semiconductor member, and one of the fourth portions is along another m-plane of the semiconductor member.

14. The semiconductor device according to claim 10, wherein
the second side further includes a plurality of first intermediate portions along a first intermediate portion direction,
one of the plurality of first intermediate portions is between one of the plurality of first portions and one of the plurality of second portions, and
the first intermediate portion direction crosses the first portion direction and crosses the second portion direction.

15. The semiconductor device according to claim 1, wherein
the first semiconductor region includes a first partial region, a second partial region, a third partial region, a fourth partial region, and a fifth partial region,
a direction from the first partial region to the first electrode is along the third direction,
a direction from the second partial region to the second electrode is along the third direction,
a direction from the third partial region to the first electrode portion is along the third direction,
a fourth position of the fourth partial region in the second direction is between a first position of the first partial region in the second direction and a third position of the third partial region in the second direction,
a fifth position of the fifth partial region in the second direction is between the third position and a second position of the second electrode in the second direction,
a direction from the fourth partial region to the first semiconductor portion is along the third direction, and
a direction from the fifth region to the second semiconductor region is along the third direction.

16. The semiconductor device according to claim 15, wherein
a part of the first electrode portion is between the fourth partial region and the fifth partial region in the second direction.

17. A semiconductor device, comprising:
a first electrode extending along a first direction;
a second electrode extending along the first direction, a second direction from the first electrode to the second electrode crossing the first direction;
a third electrode extending along the first direction, a position of the third electrode in the second direction being between a first electrode position of the first electrode in the second direction and a second electrode position of the second electrode in the second direction; and
a semiconductor member,
the semiconductor member including:
a first semiconductor region including Alₓ₁Ga₁₋ₓ₁N (0 ≤x1<1), and
a second semiconductor region including Alₓ₂Ga₁₋ₓ₂N (x1<x2≤1),
the first semiconductor region including a first partial region, a second partial region, a third partial region, a fourth partial region, and a fifth partial region,
a direction from the first partial region to the first electrode being along a third direction crossing a plane including the first direction and the second direction,
a direction from the second partial region to the second electrode being along the third direction,
a direction from the third partial region to the third electrode being along the third direction,
a fourth position of the fourth partial region in the second direction being between a first position of the first partial region in the second direction and a third position of the third partial region in the second direction,
a fifth position of the fifth partial region in the second direction being between the third position and a second position of the second electrode in the second direction,
a direction from the fifth partial region to the second semiconductor region being along the third direction,
a direction from a part of the third electrode to the fifth partial region being along the second direction,
the second semiconductor region including a side face facing the third electrode in the second direction,
the side face including a plurality of first portions along a first partial direction and a plurality of second portions along a second partial direction,
one of the plurality of first portions being between one of the plurality of second portions and another one of the plurality of second portions,
the first portion direction being inclined with respect to the second direction, and
the second portion direction crossing the first portion direction.

18. The semiconductor device according to claim 17, wherein
the second portion direction is inclined in an opposite direction to the first portion direction with respect to the second direction.

19. The semiconductor device according to claim 18, wherein
a sum of the first angle between the first partial direction and the second direction and a second angle between the second partial direction and the second direction is not less than 160 degrees and not more than 200 degrees.

20. The semiconductor device according to claim 17, wherein
one of the first portions is along an a-plane of the semiconductor member and one of the second portions is along another a-plane of the semiconductor member, or one of the first portions is along an m-plane of the semiconductor member and one of the second portions is along another m-plane of the semiconductor member.
